(19) United States
(12) Patent Application Publication
(10) Pub. No.: US 2013/0111285 A1
(43) Pub. Date: May 2, 2013

(54) SCAN TEST CIRCUITRY COMPRISING SCAN CELLS WITH FUNCTIONAL OUTPUT MULTIPLEXING

(71) Applicants: Sreejit Chakravarty, Mountain View, CA (US); Cam Luong Lu, Milpitas, CA (US)

(72) Inventors: Sreejit Chakravarty, Mountain View, CA (US); Cam Luong Lu, Milpitas, CA (US)

(73) Assignee: LSI Corporation, Milpitas, CA (US)

(21) Appl. No.: 13/283,070

(22) Filed: Oct. 27, 2011

(51) Int. Cl. G01R 31/3177; G06F 11/25

(52) U.S. Cl. 714/726; 714/E11.155

(57) ABSTRACT

An integrated circuit comprises scan test circuitry and additional circuitry subject to testing utilizing the scan test circuitry. The scan test circuitry comprises at least one scan chain having a plurality of scan cells, with the scan chain being configured to operate as a serial shift register in a scan shift mode of operation and to capture functional data from at least a portion of the additional circuitry in a functional mode of operation. At least a given one of the scan cells of the scan chain comprises multiplexing circuitry configured to select one of multiple data lines of the scan cell for application to a functional output of the scan cell. For example, the multiplexing circuitry may comprise an output multiplexer configured to select between data outputs of master and slave flip-flops for connection to the functional output of the scan cell responsive to a test mode select.

### BACKGROUND

Integrated circuits are often designed to incorporate scan test circuitry that facilitates testing for various internal fault conditions. Such scan test circuitry typically comprises scan chains, which are chains of flip-flops that are used to form serial shift registers for applying test patterns at inputs to combinational logic of the integrated circuit and for reading out the corresponding results.

A given one of the flip-flops of the scan chain may be viewed as an example of what is more generally referred to herein as a “scan cell.” A scan cell may comprise a single flip-flop, or multiple flip-flops.

In one exemplary arrangement, an integrated circuit with scan test circuitry may have a scan shift mode of operation and a functional mode of operation. A flag may be used to indicate whether the integrated circuit is in scan shift mode or functional mode. In the scan shift mode, the flip-flops of the scan chain are configured as a serial shift register. A test pattern is then shifted into the serial shill register formed by the flip-flops of the scan chain. Once the desired test pattern has been shifted in, the scan shift mode is disabled and the integrated circuit is placed in its functional mode. Internal combinational logic results occurring during this functional mode of operation are then captured by the chain of scan flip-flops. The integrated circuit is then once again placed in its scan shift mode of operation, in order to allow the captured combinational logic results to be shifted out of the serial shift register formed by the scan flip-flops, as a new test pattern is being scanned in. This process is repeated until all desired test patterns have been applied to the integrated circuit.

As integrated circuits have become increasingly complex, scan compression techniques have been developed which reduce the number of test patterns that need to be applied when testing a given integrated circuit, and therefore also reduce the required test time. Additional details regarding compressed scan testing are disclosed in U.S. Pat. No. 7,831,876, entitled “Testing a Circuit with Compressed Scan Subsets,” which is commonly assigned herewith and incorporated by reference herein.

Nonetheless, a need remains for further improvements in scan test circuitry. For example, conventional scan test circuitry can be problematic when used in certain scan testing applications, such as scan testing of high-speed registers of a processor or other type of integrated circuit.

### SUMMARY

Illustrative embodiments of the invention provide improved circuitry and techniques for scan testing of integrated circuits. For example, in one or more such embodiments, scan test circuitry of an integrated circuit is configured to include at least one scan chain that comprises at least one scan cell, with the scan cell being configured to implement functional output multiplexing between data outputs of respective master and slave flip-flops of that scan cell. Such a scan cell advantageously avoids the above-noted problems associated with use of conventional master-slave scan cell arrangements in high-speed registers and other types of scan testing applications.

In one embodiment of the invention, an integrated circuit comprises scan test circuitry and additional circuitry subject to testing utilizing the scan test circuitry. The scan test circuitry comprises at least one scan chain having a plurality of scan cells, with the scan chain being configured to operate as a serial shift register in a scan shift mode of operation and to capture functional data from at least a portion of the additional circuitry in a functional mode of operation. At least a given one of the scan cells of the scan chain comprises multiplexing circuitry configured to select one of a plurality of data lines of the scan cell for application to a functional output of the scan cell.

The given scan cell may illustratively comprise a master flip-flop having a data input and a data output, and a slave flip-flop having a data input and a data output, with the data input of the slave flip-flop being coupled to the data output of the master flip-flop. The multiplexing circuitry in an arrangement of this type may comprise an output multiplexer configured to select one of the data output of the master flip-flop and the data output of the slave flip-flop for connection to the functional output of the scan cell responsive to a logic state of a test mode select signal.

In this or another embodiment of the invention, the given scan cell may further comprise a functional data input, a scan input, and a scan enable input. In such an arrangement, the multiplexing circuitry may further comprise an input multiplexer configured to select one of the functional data input and the scan input for connection to the data input of the master flip-flop responsive to a logic state of a scan enable signal applied to the scan enable input.

In this or another embodiment of the invention, a scan cell is configured to be arranged with a plurality of other scan cells into a scan chain having a scan shift mode of operation and a functional mode of operation. The scan cell comprises multiplexing circuitry configured to select one of a plurality of data lines of the scan cell for application to a functional output of the scan cell.

Such a scan cell configuration in one or more of the illustrative embodiments provides significantly improved scan testing performance, particularly in high-speed applications such as testing of integrated circuit registers.

### BRIEF DESCRIPTION OF THE DRAWINGS

FIG. 1 is a block diagram showing an integrated circuit testing system comprising a ester and an integrated circuit under test in an illustrative embodiment.

FIG. 2 illustrates one example of the manner in which scan chains may be arranged between combinational logic in the integrated circuit of FIG. 1.

FIG. 3 shows a scan cell that may be implemented in one of the scan chains of FIG. 2,

FIG. 4 is a timing diagram illustrating the operation of the scan cell of FIG. 3.

FIG. 5 shows a scan cell that is implemented in one of the scan chains of FIG. 2 in an illustrative embodiment.

FIG. 6 shows one possible implementation of the testing system of FIG. 1.

FIG. 7 is a block diagram of a processing system for generating an integrated circuit design comprising one or more scan chains each having one or more scan cells of the type shown in FIG. 5.

### DETAILED DESCRIPTION

Embodiments of the invention will be illustrated herein in conjunction with exemplary testing systems and corresponding integrated circuits comprising scan test circuitry for supporting scan testing of other internal circuitry of those integrated circuits. It should be understood, however, that embodiments of the invention are more generally applicable to any testing system or associated integrated circuit in which it is desirable to provide improved scan testing performance, particularly in high-speed applications such as those involving registers.

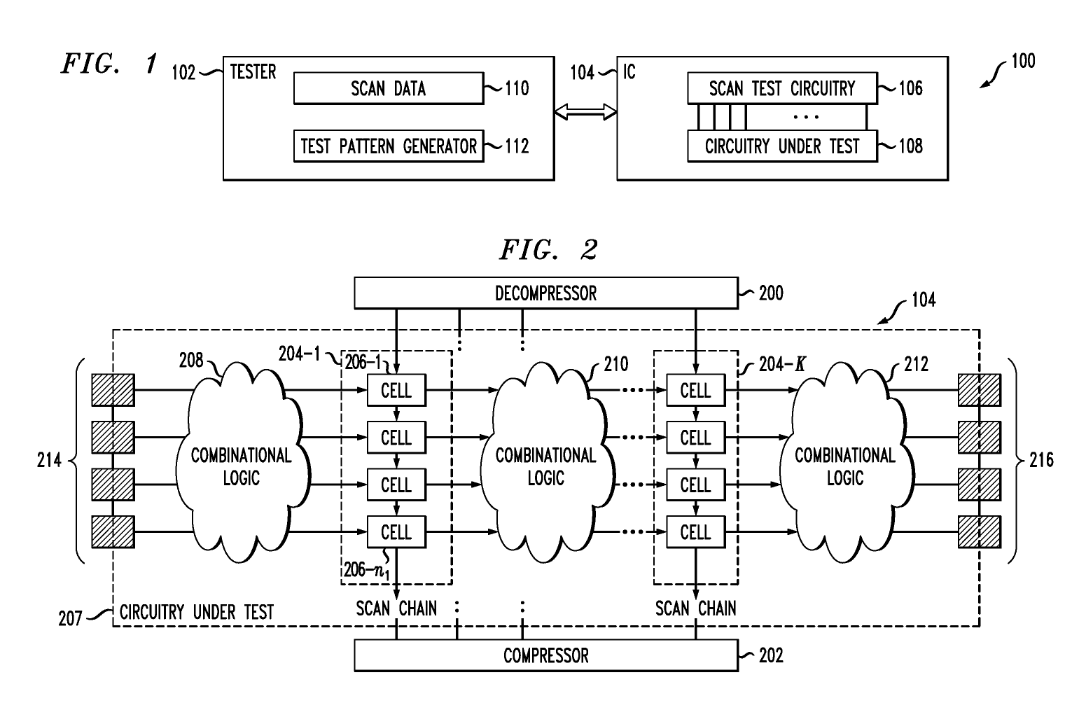

FIG. 1 shows a testing system 100 comprising a tester 102 and an integrated circuit under test 104. The integrated circuit 104 comprises scan test circuitry 106 that is coupled to additional internal circuitry 108 that is subject to testing utilizing the scan test circuitry 106. The tester 102 stores scan data 110 associated with scan testing of the integrated circuit. Such scan data may correspond to test patterns provided by a test pattern generator 112. In other embodiments, at least a portion of the tester 102, such as the test pattern generator 112, may be incorporated into the integrated circuit 104. Alternatively, the entire tester 102 may be incorporated into the integrated circuit 104.

The particular configuration of testing system 100 as shown in FIG. 1 is exemplary only, and the testing system 100 in other embodiments may include other elements in addition to or in place of those specifically shown, including one or more elements of a type commonly found in a conventional implementation of such a system. For example, various elements of the tester 102 or other parts of the system 100 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

Embodiments of the invention may be configured to utilize compressed or noncompressed scan testing, and embodiments of the invention are not limited in this regard. However, the embodiment of the invention shown in FIG. 2 will be described primarily in the context of compressed scan testing.

Referring now to FIG. 2, portions of one potential configuration of the integrated circuit 104 are shown in greater detail. In this compressed scan testing arrangement, the scan test circuitry 106 comprises a decompressor 200, a compressor 202, and a plurality of scan chains 204-k, where k=1, 2, . . . K. Each of the scan chains 204 comprises a plurality of scan cells 206, and is configurable to operate as a serial shift register in a scan shift mode of operation of the integrated circuit 104 and to capture functional data from circuitry under test 207 in a functional mode of operation of the integrated circuit 104.

The scan chains 204 are arranged in parallel with one another between respective outputs of the decompressor 200 and respective inputs of the compressor 202, such that in the scan shift mode of operation, scan test input data from the decompressor 200 is shifted into the scan chains 204 and scan test output data is shifted out of the scan chains 204 into the compressor 202.

The decompressor 200 and compressor 202 may be combinational or sequential, and the functionality disclosed herein does not require any particular combinational or sequential compression arrangement.

The first scan chain 204-1 is of length n₁ and therefore comprises n₁ scan cells denoted 206-1 through 206-n₁. More generally', scan chain 204-k is of length nₖ and therefore comprises a total of nₖ scan cells. Circuitry under test 207 in this embodiment comprises a plurality of combinational logic blocks, of which exemplary blocks 208, 210 and 212 are shown. The combinational logic blocks are illustratively arranged between primary inputs 214 and primary outputs 216 and separated from one another by the scan chains 204.

Combinational logic blocks such as 208, 210 and 212 may be viewed as examples of what are more generally referred to herein as “additional circuitry” that is subject to testing utilizing scan test circuitry in embodiments of the invention. By way of example, such blocks may represent portions of different integrated circuit cores, such as respective read channel and additional cores of a system-on-chip (SOC) integrated circuit in a hard disk drive (HDD) controller application. In other embodiments, the circuit blocks subject to testing by the scan chains may comprise other types of functional logic circuitry, in any combination, and the term “additional circuitry” is intended to be broadly construed so as to cover any such arrangements of logic circuitry.

The number K of scan chains 204 is generally much larger than a number N of scan test outputs of the compressor 202. The ratio of K to N provides a measure of the degree of scan test pattern compression implemented in the scan test circuitry 106. It should be noted, however, that the number of compressor outputs need not be the same as the number of decompressor inputs. For example, there may be N decompressor inputs and L compressor outputs, where N≠L but both N and L are much smaller than K.

The decompressor 200 receives compressed scan data from the tester 102 and decompresses that scan data to generate scan test input data that is shifted into the scan chains 204 when such chains are configured as respective serial shift registers in the scan shift mode of operation. The compressor 202 receives scan test output data shifted out of the scan chains 204, also when such chains are configured as respective serial shift registers in the scan shift mode of operation, and compresses that scan test output data for delivery back to the tester 102. Additional details regarding the operation of scan compression elements such as decompressor 200 and compressor 202 may be found in the above-cited U.S. Pat. No. 7,831,876. Again, scan compression elements such as decompressor 200 and compressor 202 may be eliminated in other embodiments.

In a typical implementation, the lengths of the scan chains 204 are balanced so that the same amount of time is needed to shill the desired set of scan test patterns into all of the scan chains. It may therefore be assumed without limitation that all of the scan chains 204 are of length n, such that n₁=n₂= . . . =nₖ=n.

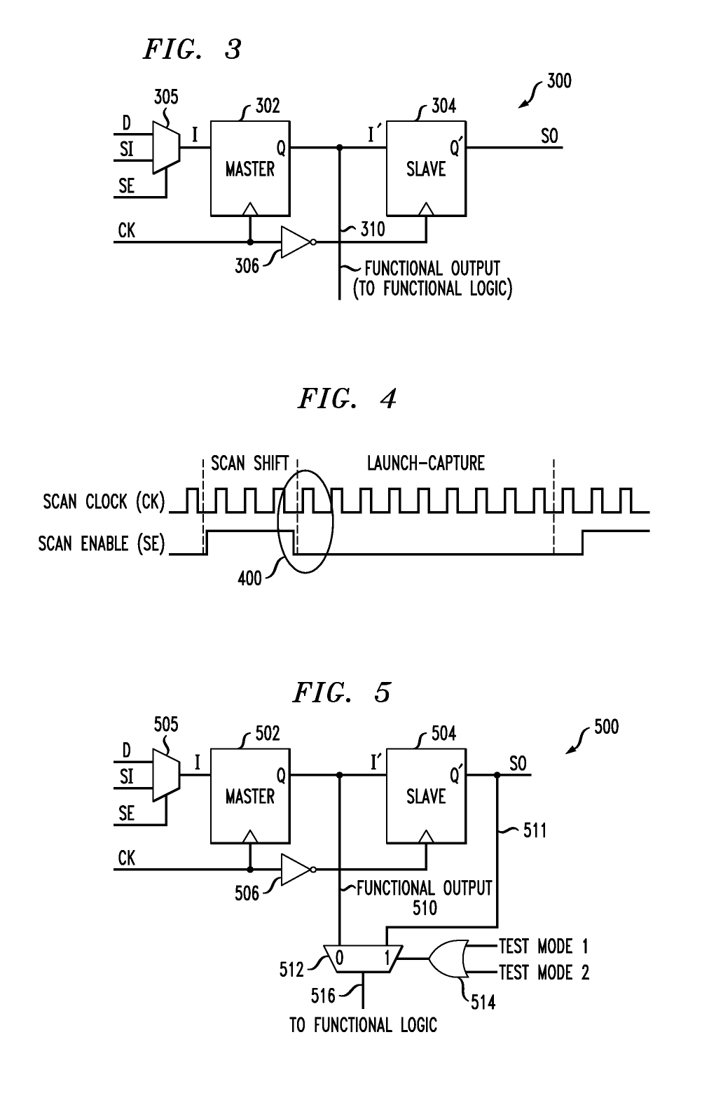

FIG. 3 shows a given scan cell 300 in an illustrative embodiment. The scan cell in this embodiment comprises a master flip-flop 302, a slave flip-flop 304, a two-to-one input multiplexer 305, and an inverter 306. Such a scan cell may be utilized as one or more of the scan cells 206 in the scan chains 204 of FIG. 2.

The scan cell 300 as shown comprises a functional data input (D), a scan input (SI), a scan enable input (SE), a scan output (SO) and a clock input (CK). Also, the master flip-flop 302 has a data input (I) and a data output (Q), and the slave flip-flop 304 has a data input (I′) and a data output (Q′).

Notations such as D, SI, SO, SE, CK and so on will be used herein to denote not only the physical inputs and outputs of the scan cell, but also the corresponding signals associated with those inputs or outputs.

The data output of the master flip-flop 302 is coupled to the data input of the slave flip-flop 304. The data output of the master flip-flop 302 in this embodiment also drives a functional output 310 of the scan cell 300. This functional output is coupled to functional logic, which may be part of one of the logic blocks 208, 210 or 212.

The master flip-flop 302 has a clock input that receives a clock signal applied to the clock input CK of the scan cell 300. The stave flip-flop 304 has a clock input that receives a complemented version of the clock signal, as provided by the inverter 306.

It will be assumed in this embodiment of the invention that a scan enable signal applied to the scan enable input SE of the scan cell 300 is at a logic “1” level when the integrated circuit 104 is in a scan shift mode of operation and at a logic “0” level when the integrated circuit 104 is in the functional mode of operation, although in other embodiments of the invention the scan enable signal can take on other values for the scan shift and functional modes. Other types and combinations of operating modes and scan enable signaling may be used in other embodiments. For example, different portions of the integrated circuit 104 and its associated scan test circuitry 106 may be controlled using separate scan enable signals.

The input multiplexer 305 is therefore operative to connect the scan input SI of the scan cell 300 to the data input I of the master flip-flop 302 in the scan shift mode of operation, and to connect the functional data input D of the scan cell 300 to the data input I of the master flip-flop 302 in the functional mode of operation.

The timing diagram of FIG. 4 illustrates the operation of the scan cell 300 in its scan shift and functional modes of operation. The CK signal in this example is more specifically referred to as a scan clock. In the scan shift mode of operation, as noted above, the scan enable signal is at a logic “1” level, as shown in the figure. When the scan enable signal is at a logic “0” level, the functional mode of operation is enabled. This mode is also referred to in the context of the present embodiment as a “launch-capture” mode. During this functional mode, data is being launched from the scan cells into portions of the combinational logic or other functional circuitry of the integrated circuit 104, and data is also being captured by the scan cells from other portions of the functional circuitry.

As mentioned previously, the scan cell 300 is configured such that the output of the master flip-flop 302 drives the functional output 310 of the scan cell. Such an arrangement is designed to allow the scan cell to operate in high-speed applications, by reducing the delay which would otherwise result if the output of the slave flip-flop were used to drive the functional output of the scan cell. The term “high-speed” in this context refers to those applications in which delay such as that associated with passage of a functional signal through an additional flip-flop can undermine operating performance.

However, we have found that such an arrangement can lead to problems during scan testing. More specifically, at the first rising edge of the clock signal CK after the scan enable signal SE goes low, as indicated generally by reference numeral 400 in FIG. 4, the input I of the master flip-flop 302 may receive uninitialized data from the D input of the scan cell. We refer to this as a “garbage generation” phase, which occurs when transitioning between the scan shift mode of operation and the functional mode of operation. Because the data applied to the D input of the scan cell during this phase can be indeterminate, it may induce changes in the desired scan pattern that was loaded in during the scan shift phase, and therefore adversely impact the accuracy of the scan test.

The scan cell 500 configured as shown in FIG. 5 provides improved performance relative to the scan cell 300 by incorporating multiplexing circuitry configured to select one of a plurality of data lines of the scan cell for application to a functional output of the scan cell. The scan cell 500 in this embodiment comprises a master flip-flop 502, a slave flip-flop 504, an input multiplexer 505, and an inverter 506. These elements are generally configured to operate in substantially the same manner as described previously for the corresponding elements of the scan cell 300 of FIG. 3.

Like the scan cell 300, the scan cell 500 comprises functional data input D, scan input SI, scan enable input SE, scan output SO and clock input CK. Also, the master flip-flop 502 has a data input I and a data output Q, and the slave flip-flop 504 has a data input I′ and a data output Q′. The data output Q of the master flip-flop 502 is coupled to the data input I′ of the slave flip-flop 504. The data output Q of the master flip-flop 502 in this embodiment also drives a data line 510 that is provided as one input to an output multiplexer 512.

The master flip-flop 502 has a clock input that receives a clock signal applied to the clock input CK of the scan cell 500. The slave flip-flop 504 has a clock input that receives a complemented version of the clock signal, as provided by the inverter 506.

It is again assumed in this embodiment that a scan enable signal applied to the scan enable input SE of the scan cell 500 is at a logic “1” level when the integrated circuit 104 is in a scan shift mode of operation and at a logic “0” level when the integrated circuit 104 is in the functional mode of operation. Other types and combinations of operating modes and scan enable signaling may be used in other embodiments.

The input multiplexer 505 is therefore operative to connect the scan input SI of the scan cell 500 to the data input I of the master flip-flop 502 in the scan shift mode of operation, and to connect the functional data input D of the scan cell 500 to the data input I of the master flip-flop 502 in the functional mode of operation.

As indicated above, the scan cell 500 comprises additional multiplexing circuitry relative to the scan cell 300. This additional multiplexing circuitry will now be described in greater detail. In the scan cell 500, data lines 510 and 511 corresponding to the Q and Q′ outputs of the respective master and slave flip-flops 502 and 504 are coupled to respective first and second inputs of a two-to-one output multiplexer 512. Responsive to a test mode select signal generated by logic gate 514, the output multiplexer 512 selects one of the data lines 510 and 511 of the scan cell 500 for application to a functional output 516 of the scan cell.

The logic gate 514 is illustratively implemented as a two-input OR gate which receives signals denoted Test Mode 1 and Test Mode 2 at its respective inputs. These test mode signals may be associated, for example, with different scan testing modes of the integrated circuit 104. In the present embodiment, if either or both of the Test Mode 1 and Test Mode 2 signals are at logic “1” signal levels, the multiplexer 512 selects the SO line 511 for application to the functional output 516 of the scan cell 500. If both of the Test Mode 1 and Test Mode 2 signals are at logic “0” signal levels, the multiplexer 512 selects the line 510 from the Q output of the master flip-flop 502 for application to the functional output 516 of the scan cell 500. Other types of test mode signals and corresponding logic circuitry for controlling multiplexer 512 can be used in other embodiments.

The output multiplexer 512 in the scan cell 500 can be advantageously utilized to eliminate the above-described garbage generation phase associated with the scan cell 300, thereby providing significantly improved scan testing performance. This performance improvement comes at the cost of additional delay in the functional path through the multiplexer 512, as well as reduced fault coverage for a portion of the functional path.

Although only a single scan cell 500 is shown in FIG. 5, it may be assumed that the other scan cells 206 of the scan chains 204 in the scan test circuitry of FIG. 2 are each configured in substantially the same manner. Alternatively, different types of scan cells may be used in different ones of the scan chains, or within the same scan chain. For example, one or more of the scan chains 204 may be configured using scan cells 500, white other ones of the scan chains may be configured using scan cells 300. Also, a given scan chain may comprise one or more of the scan cells 300 as well as one or more of the scan cells 500.

A scan cell of the type shown in FIG. 5 may be generated by modifying a standard scan cell from an integrated circuit design library to incorporate the functional output multiplexing circuitry in the form of a wrapper around the standard cell. This can be achieved without requiring the modification of any internal signaling or timing features of the standard cell, and without adding ports, extra flip-flops or other internal circuitry to the standard cell itself. The additional circuit area needed to accommodate the functional output multiplexing feature of the scan cell 500 is minimal.

It should be noted that other types of scan cells and functional output multiplexing arrangements may be used in other embodiments. The two-to-one multiplexer 512 as used in scan cell 500 is therefore just one example of what is more generally referred to herein as “multiplexing circuitry.”

As mentioned above, a scan cell configured as shown in FIG. 5 can provide significantly improved scan testing performance, particularly in high-speed applications involving testing of integrated circuit registers and other types of circuitry that operate at high speed. Such performance improvements are provided without adversely impacting signaling and timing of the scan test circuitry. Existing scan flip-flops or other types of scan cells can be easily replaced with the modified scan cells without unduly increasing the area or power requirements of the scan test circuitry.

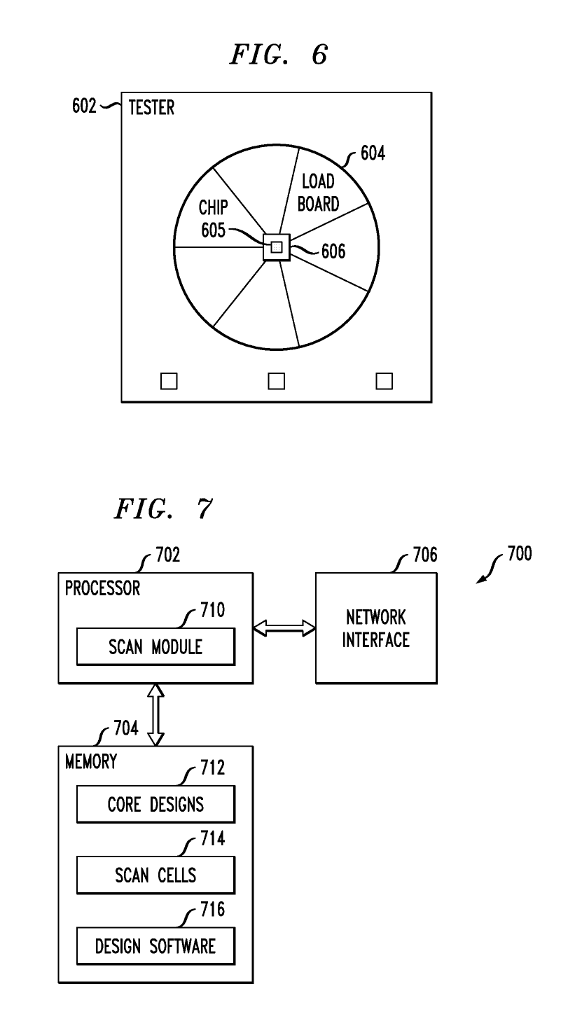

The tester 102 in the testing system 100 of FIG. 1 need not take any particular form, and various conventional testing system arrangements can be modified in a straightforward manner to support the functional output multiplexing feature of the scan cell 500. One possible example is shown in FIG. 6, in which a tester 602 comprises a load board 604 in which an integrated circuit 605 to be subject to scan testing using the techniques disclosed herein is installed in a central portion 606 of the load board 604. The tester 602 may also comprise processor and memory elements for executing stored computer code, although such elements are not explicitly shown in the figure. Numerous alternative testers may be used to perform scan testing of an integrated circuit as disclosed herein.

The insertion of scan cells to form scan chains in scan test circuitry of an integrated circuit design may be performed in a processing system 700 of the type shown in FIG. 7. Such a processing system is configured for use in designing integrated circuits such as integrated circuit 104 to include scan test circuitry 106. The processing system 700 comprises a processor 702 coupled to a memory 704. Also coupled to the processor 702 is a network interface 706 for permitting the processing system to communicate with other systems and devices over one or more networks. The network interface 706 may therefore comprise one or more transceivers. The processor 702 implements a scan module 710 for supplementing core designs 712 with scan cells 714 in the manner disclosed herein, in conjunction with utilization of integrated circuit design software 716.

Elements such as 710, 712, 714 and 716 are implemented at least in part in the form of software stored in memory 704 and processed by processor 702. For example, the memory 704 may store program code that is executed by the processor 702 to implement particular scan cell insertion functionality of module 710 within an overall integrated circuit design process. The memory 704 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 702 may comprise a microprocessor, CPU, ASIC, FPGA or other type of processing device, as well as portions or combinations of such devices.

As indicated above, embodiments of the invention may be implemented in the form of integrated circuits. In a given such integrated circuit implementation, identical die are typically formed in a repeated pattern on a surface of a semiconductor wafer. Each die includes scan test circuitry as described herein, and may include other structures or circuits. The individual die are cut or diced from the wafer, then packaged as an integrated circuit. One skilled in the art would know how to dice wafers and package die to produce integrated circuits. Integrated circuits so manufactured are considered part of one or more embodiments of this invention.

Again, it should be emphasized that the embodiments of the invention as described herein are intended to be illustrative only. For example, other embodiments of the invention can be implemented using a wide variety of other types of scan test circuitry, with different types and arrangements of scan cells, multiplexing circuitry, logic gates and other circuit elements, than those previously described in conjunction with the illustrative embodiments. These and numerous other alternative embodiments of the invention within the scope of the following claims will be readily apparent to those skilled in the art.

What is claimed is:

1. An integrated circuit comprising:
scan test circuitry; and
additional circuitry subject to testing utilizing the scan test circuitry;
the scan test circuitry comprising at least one scan chain having a plurality of scan cells, the scan chain being configured to operate as a serial shift register in a scan shift mode of operation and to capture functional data from at least a portion of the additional circuitry in a functional mode of operation;
wherein at least a given one of the scan cells of the scan chain comprises multiplexing circuitry configured to select one of a plurality of data lines of the scan cell for application to a functional output of the scan cell.

2. The integrated circuit of claim 1 wherein the given scan cell further comprises:
a master flip-flop having a data input and a data output; and
a slave flip-flop having a data input and a data output, with the data input of the slave flip-flop being coupled to the data output of the master flip-flop.

3. The integrated circuit of claim 2 wherein said multiplexing circuitry comprises an output multiplexer configured to select one of the data output of the master flip-flop and the data output of the slave flip-flop for connection to the functional output of the scan cell responsive to a logic state of a test mode select signal.

4. The integrated circuit of claim 3 wherein the output multiplexer comprises a two-to-one multiplexer having a first input coupled to the data output of the master flip-flop, a second input coupled to the data output of the slave flip-flop, and a select line coupled to an output of a mode select circuit.

5. The integrated circuit of claim 4 wherein the mode select circuit comprises a logic gate having a first input coupled to a first test mode signal input of the scan cell and a second input coupled to a second test mode signal input of the scan cell.

6. The integrated circuit of claim 5 wherein the logic gate comprises a logic OR gate.

7. The integrated circuit of claim 2 wherein the given scan cell further comprises:
a functional data input;
a scan input; and
a scan enable input;
wherein said multiplexing circuitry further comprises an input multiplexer configured to select one of the functional data input and the scan input for connection to the data input of the master flip-flop responsive to a logic state of a scan enable signal applied to the scan enable input.

8. The integrated circuit of claim 7 wherein the input multiplexer comprises a two-to-one multiplexer having a first input coupled to the functional data input, a second input coupled to the scan input, and a select line coupled to the scan enable input.

9. The integrated circuit of claim 2 wherein the master flip-flop has a clock input adapted to receive a clock signal and the slave flip-flop has a clock input adapted to receive a complemented version of the clock signal.

10. The integrated circuit of claim 9 wherein the given scan cell comprises an inverter having an input adapted to receive the clock signal and an output providing the complemented version of the clock signal.

11. A disk drive controller comprising the integrated circuit of claim 1.

12. A method of scan testing an integrated circuit, comprising:
configuring a scan chain having a plurality of scan cells to operate as a serial shift register in a scan shift mode of operation and to capture functional data from the integrated circuit in a functional mode of operation; and
selecting one of a plurality of data lines of a given scan cell of the scan chain for application to a functional output of the scan cell.

13. The method of claim 12 wherein the given scan cell comprises a master flip-flop and a slave flip-flop, with a data output of the master flip-flop being coupled to a data input of the slave flip-flop, and wherein the selecting step comprises selecting one of the data output of the master flip-flop and a data output of the slave flip-flop for connection to the functional output of the scan cell responsive to a logic state of a test mode select signal.

14. The method of claim 12 wherein the given scan cell comprises a master flip-flop and a slave flip-flop, with a data output of the master flip-flop being coupled to a data input of the slave flip-flop, and the given scan cell further comprises a functional data input, a scan input, and a scan enable input, and wherein the method further comprises the step of selecting one of the functional data input and the scan input for connection to a data input of the master flip-flop responsive to a logic state of a scan enable signal applied to the scan enable input.

15. A computer program product comprising a non-transitory computer-readable storage medium having computer program code embodied therein for use in scan testing an integrated circuit, wherein the computer program code when executed in a testing system causes the testing system to perform the steps of the method of claim 12.

16. A processing system comprising:
a processor; and
a memory coupled to the processor and configured to store information characterizing an integrated circuit design;
wherein the processing system is configured to provide within the integrated circuit design scan test circuitry comprising at least one scan chain having a plurality of scan cells, the scan chain being configured to operate as a serial shift register in a scan shift mode of operation and to capture functional data from at least a portion of additional circuitry of the integrated circuit in a functional mode of operation;
wherein at least a given one of the scan cells of the scan chain comprises multiplexing circuitry configured to select one of a plurality of data lines of the scan cell for application to a functional output of the scan cell.

17. An apparatus for use in scan testing an integrated circuit, the apparatus comprising:
a scan cell configured to be arranged with a plurality of other scan cells into a scan chain having a scan shift mode of operation and a functional mode of operation;
wherein the scan cell comprises multiplexing circuitry configured to select one of a plurality of data lines of the scan cell for application to a functional output of the scan cell.

18. The apparatus of claim 17 wherein the scan cell further comprises:
a master flip-flop having a data input and a data output; and
a slave flip-flop having a data input and a data output, with the data input of the stave flip-flop being coupled to the data output of the master flip-flop.

19. The apparatus of claim 18 wherein said multiplexing circuitry comprises an output multiplexer configured to select one of the data output of the master flip-flop and the data output of the slave flip-flop for connection to the functional output of the scan cell responsive to a logic state of a test mode select signal.

20. The apparatus of claim 18 wherein the scan cell further comprises:
a functional data input;
a scan input; and
a scan enable input;
wherein said multiplexing circuitry further comprises an input multiplexer configured to select one of the functional data input and the scan input for connection to the data input of the master flip-flop responsive to a logic state of a scan enable signal applied to the scan enable input.
